(19) United States
(12) Patent Application Publication
(10) Pub. No.: US 2011/0099407 A1
(43) Pub. Date: Apr. 28, 2011

(54) Apparatus for High Speed Data Multiplexing in a Processor

(75) Inventor: William A. Jonas, Mt. Albert (CA)

(73) Assignee: ATI TECHNOLOGIES ULC, Markham (CA)

(21) Appl. No.: 12/607,716

(22) Filed: Oct. 28, 2009

(51) Int. Cl. G06F 13/42; H03K 19/177; H03K 19/00

(52) U.S. Cl. 713/400; 326/39; 326/93

(57) ABSTRACT

A processer, for example a field programmable gate array (FPGA), comprises input/output (I/O) logic including timing adjustment logic operative to synchronize a time division multiplexed (TDM) line of the I/O logic using an a priori known test pattern. The timing adjustment logic may include clock cycle data alignment logic operative to adjust data on the TDM line by increments of a clock cycle to match it to an a priori known test pattern, and skew logic operative to prevent leading or trailing edges of the data from aligning with edges of a clock pulse leading or trailing edge. The I/O logic may be a Serializer/Deserializer (SerDes) logic that includes a state machine operative to control the clock cycle data alignment logic and skew logic to adjust and synchronize the data with the known test pattern.

### FIELD OF THE DISCLOSURE

The present disclosure is related to field programmable gate arrays (FPGAs) and application specific integrated circuits (ASICs).

### BACKGROUND

The design and prototyping of Application Specific Integrated Circuit (ASIC), is often achieved by using a plurality of Field Programmable Gate Arrays (FPGAs), having interconnections between various FPGAs. Typically these FPGA connections are multiplexed so that the total number of pins between the FPGAs is reduced. For example, various ratios of multiplexing may be used such as 10 to 1 pin multiplexing schemes or 32 to 1 pin multiplexing schemes or any of various ratios that may be desirable. Such multiplexing is achieved by using shift registers as multiplexers and de-multiplexers on the transmitting and receiving side FPGAs, respectively. FIG. 1 illustrates a prior system of prototyping an ASIC 100 by using two FPGAs, FPGA 101 and FPGA 103. The FPGAs are interconnected via a plurality of connection pins or trace lines 105. In order to reduce the number of connection lines or trace lines needed to connect to FPGAs multiplexing schemes such as those shown in FIG. 2 was used in prior systems. The transmitting FPGA 201 includes an output multiplexing logic 207 which is, for example, a shift register. The receiving side FPGA 203, includes an input de-multiplexing logic 209, which is also a shift register. The multiplexing/de-multiplexing scheme achieves a multiplexed trace line or trace lines 205 that have a ratio of the actual FPGA output pins to a reduced number of trace lines preferably a single multiplex trace line 205. A difficulty with such multiplex trace lines occurs in that the shift registers are limited by the fabric speeds at which the FPGA can run. For example, for an FPGA capable of running at speeds of 64 megahertz and possibly up to 100 megahertz, a 32 to 1 pin multiplexing ratio would result in a circuit speed of approximately only 3 megahertz. Therefore, the prototype and emulation speed is very slow while designers would normally desire to run such simulations as fast as possible.

Therefore, what is needed are apparatuses and methods that allow for high speed data multiplexing in a field programmable gate array.

### BRIEF DESCRIPTION OF THE DRAWINGS

FIG. 1 is a block diagram of two connected FPGAs for emulating an ASIC and having a plurality of trace line connections between the two FPGAs.

FIG. 2 is a block diagram showing a prior shift register based multiplexed trace line connection between two FPGAs.

FIG. 3 is a block diagram of an FPGA having an I/O logic and a mux/demux logic, a timing adjustment logic and a test pattern logic in accordance with the embodiments.

FIG. 4 is a block diagram of an embodiment of the FPGA shown in FIG. 3 and showing further details.

FIG. 5 is a block diagram showing a connection between two FPGAs in accordance with an embodiment.

FIG. 6 is a timing diagram showing a skew adjustment in accordance with an embodiment.

FIG. 7 is a block diagram of an FPGA for connection to a plurality of other FPGAs in accordance with an embodiment.

FIG. 8 is a block diagram of an FPGA array in accordance with an embodiment.

FIG. 9 is a flow chart of an operation in accordance with an embodiment.

FIG. 10 is a flow chart showing further details of a block from the flow chart of FIG. 9, in accordance with an embodiment.

FIG. 11 is a flow chart that summarized operation in accordance with an embodiment.

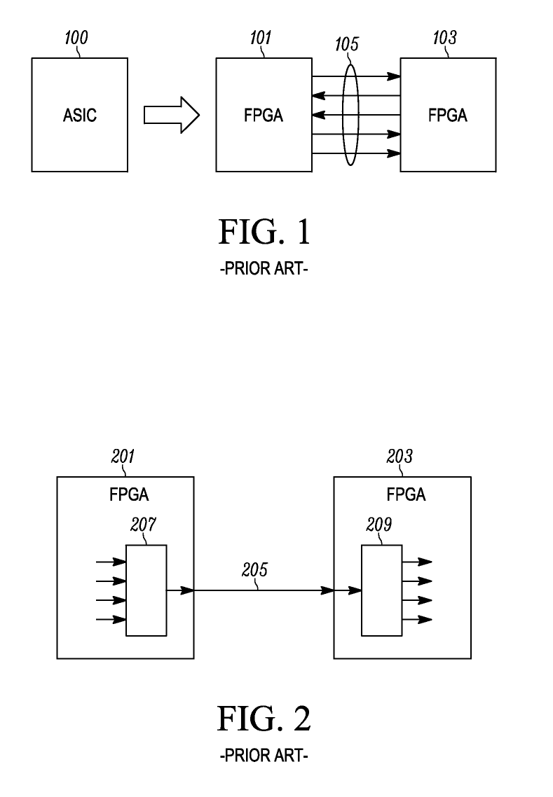

### DETAILED DESCRIPTION

The present disclosure provides a processor, for example a field programmable gate array (FPGA), comprising input/output (I/O) logic including timing adjustment logic operative to synchronize a time division multiplexed (TDM) line of said I/O logic using an a priori known test pattern. The timing adjustment logic may further include clock cycle data alignment logic, operative to adjust data on the TDM line by increments of a clock cycle to match the a priori known test pattern; and skew logic operative to prevent leading or trailing edges of the data from aligning with edges of a clock pulse leading or trailing edge. The I/O logic may utilize Serializer/Deserializer (SerDes, aka SERDES) logic to provide a TDM output and receive a TDM input. The timing adjustment logic in some embodiments may be realized by a state machine of the SerDes logic, where the state machine controls the clock cycle data alignment logic and skew logic to adjust the data to match the a priori known test pattern.

An FPGA of the embodiments may include a plurality of I/O logic blocks to interface to other FPGAs so that an FPGA array can be realized. Thus each FPGA may further include switching logic operatively coupled to a plurality of I/O logic blocks, and operatively coupled to the timing adjustment logic, wherein each I/O logic block is operative to provide I/O connections with another FPGA, and where the switching logic is operative to connect the timing adjustment logic to each I/O logic block one at a time in a serial manner, to synchronize each I/O logic block one at a time in a serial manner. An alternative embodiments may include a plurality of timing adjustment logic blocks, one for each corresponding I/O logic block, wherein each timing adjustment logic synchronizes its corresponding I/O logic block. The FPGA of the embodiments further includes a test pattern logic for sending the a priori known test pattern to other FPGAs over a corresponding TDM output line.

The present disclosure also provides a multiplexer/de-multiplexer (mux/demux) logic that includes timing adjustment logic operative to synchronize a time division multiplexed (TDM) output line of the mux/demux logic using an a priori known test pattern. The timing adjustment logic may also include the clock cycle data alignment logic and skew logic as discussed above for the other embodiments. The mux/demux logic may be an FPGA SerDes logic that may be used in place of the prior systems, such as shift register based multiplexing systems. The SerDes logic of the embodiments may thus replace prior systems. The mux/demux logic, or in this case, the SerDes logic, may include a state machine to control the clock cycle data alignment logic using a BITSLIP logic and control the skew logic using a tap delay logic.

The various logic disclosed herein may be described in Hardware Description Language (HDL) and RTL and may be stored on a computer readable medium. The computer readable medium may be a computer readable memory and may be any suitable non-volatile memory such as, but not limited to, programmable chips such as EEPROMS, flash ROM (thumb drives), compact discs (CDs) digital video disks (DVDs), etc., (that may be used to load HDL and/or RTL, and/or executable instructions or program code), or any other suitable medium so that the HDL or RTL may be used by various integrated circuit fabrication systems. Therefore, the embodiments herein disclosed include a computer readable memory comprising executable instructions for execution by an integrated circuit production system, that when executed cause the system to produce an integrated circuit comprising a timing adjustment logic operative to synchronize a TDM line of the integrated circuit I/O logic using an a priori known test pattern. The executable instructions may be HDL or RTL code and may include code to produce all of the features of the embodiments described above, and also described in further detail herein below. The embodiments also include an array of FPGAs connected using the I/O and/or mux/demux logic described above, and also described in further detail herein below.

The term “logic” as used herein may include software and/or firmware executing on one or more programmable processors, ASICs, FPGAs, DSPs, hardwired logic or combinations thereof. Therefore, in accordance with the embodiments, various logic may be implemented in any appropriate fashion and would remain in accordance with the embodiments herein disclosed. The logic may be represented in HDL and/or RTL which may be stored on a computer readable medium/memory.

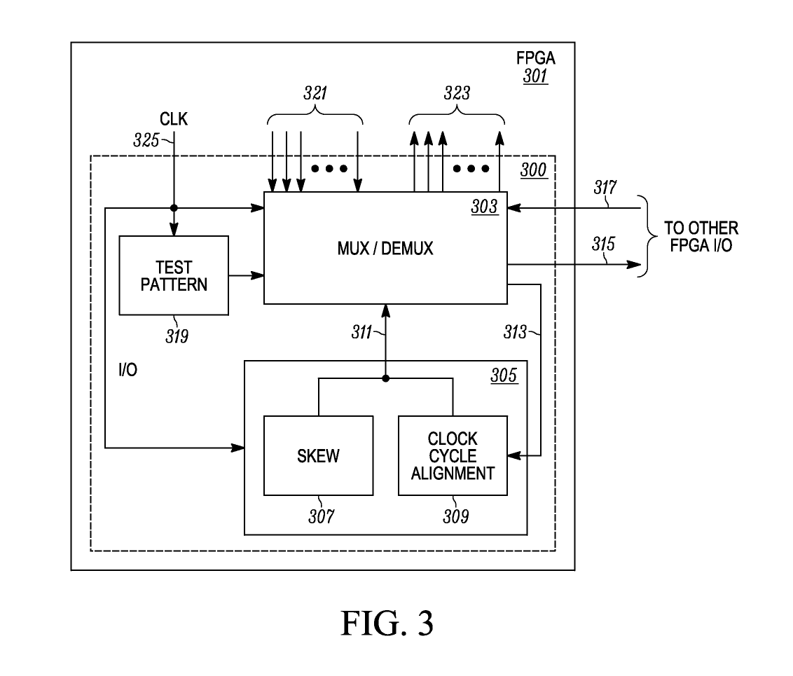

Turning now to the drawings wherein like numerals represent like components, FIG. 3 illustrates an FPGA 301 having an input output (I/O) logic in accordance with the embodiments. The I/O logic 300 includes a mux/demux logic 303 which provides a multiplexed output trace lane 315 and receives a multiplexed input trace line 317 to and from another external FPGA I/O. The other external FPGA I/O is similar to the FPGA 301 I/O logic 300 and includes the same components which will now be described in detail. As shown in FIG. 3, mux/demux 303 is operatively coupled to a timing adjustment logic 305 and a test pattern logic 319. The timing adjustment logic 305 provides a data timing adjustment line 311 to adjust the input data received by the mux/demux logic 303. The test pattern logic 319 provides a known test pattern to the mux/demux 303 as will be described further herein. The timing adjustment logic 305 may include two components, the clock cycle alignment logic 309 and the skew adjustment logic 307. The clock cycle alignment logic 309 receives an input feedback 313 from the mux/demux 303. All of the various components such as the mux/demux 303, the test pattern logic 319, and the data adjustment logic 305 receive a clock signal such as clock signal 325. The mux/demux 303 receives output pins 321 from the FPGA fabric. Likewise, the mux/demux 303 provides input pins 323 to the FPGA fabric. The mux/demux logic 303 is operative to multiplex the output pins 321 from the FPGA 301 fabric and reduce them to a single multiplexed output trace line 315. Likewise, the multiplexing portion of the mux/demux 303 is operative to receive a single multiplexed input trace line 317 and de-multiplex it to produce the needed input pins 323 to the FPGA fabric.

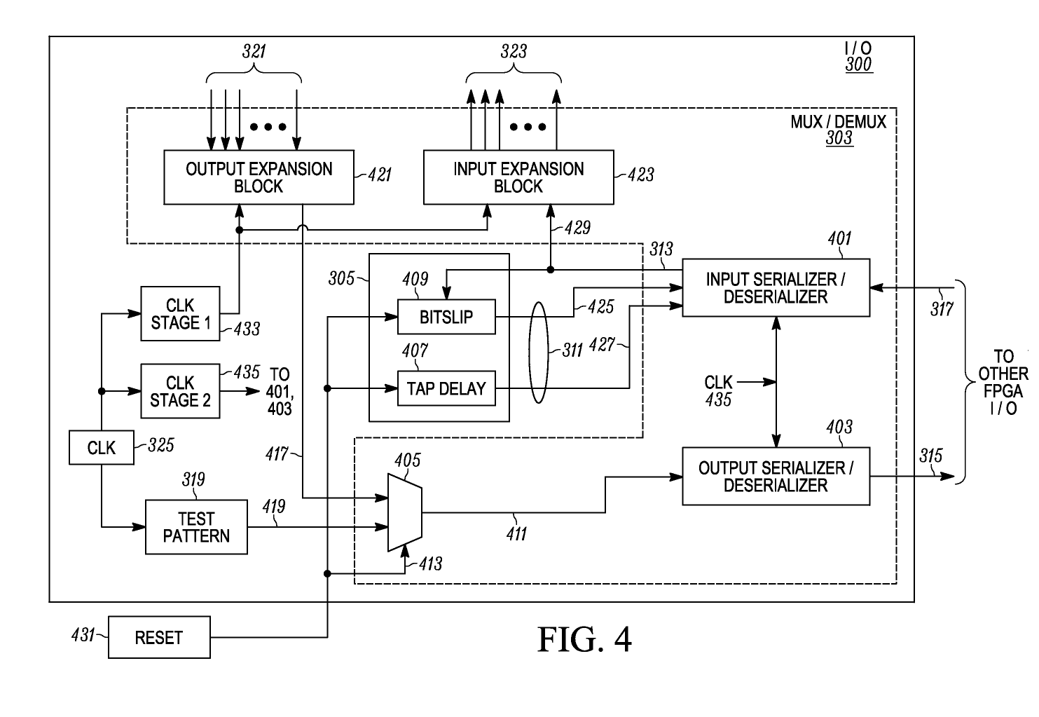

Turning to FIG. 4, further details of the mux/demux 303 of the I/O logic 300 are illustrated. As can be seen the input and output pins from the FPGA 301 fabric, are first run through the output expansion block 421 or received through the input expansion block 423. For example, the output expansion block 421 received the input lines 321 from the FPGA 301 fabric and may multiplex and reduce them down to a first level multiplexed output 417. This output is then fed into the multiplexer or mux 405. The mux 405 is operative to allow either the output expansion block first level multiplexed output 417 or the test pattern 319 to be input to the output serializer/deserializer 403 via the mux output 411. An external reset signal 431, which provides a reset via a reset bus, provides a mux reset 413 to the mux 405. The output serializer/deserializer 403 is capable of, and operative to, provide the multiplexed output trace line 315 which can be run at a speed of up to a gigahertz. Therefore, the various embodiments described herein allow an FPGA emulation of an ASIC to be run at significantly higher speeds than was the case in prior systems.

FIG. 4 also illustrates the input serializer/deserializer 401, which receives a single multiplexed input trace line 317. The input serializer/deserializer 401 provides an input feedback 313 to a timing adjustment logic 305. In the embodiment shown in FIG. 4, the timing adjustment logic 305 includes a bitslip adjustment logic 409 and a tap delay clock skew adjustment logic 407. The timing adjustment logic in general provides a data timing adjustment signal 311 which, in the case of FIG. 4, includes the bitslip data adjustment signal 425, and the tap delay clock skew adjustment signal 427. The input serializer/deserializer 401 receives the multiplexed input from the multiplexed input trace line 317 and reduces that signal to a second level multiplexed input 429 which is provided to the input expansion block 423. The input expansion block 423 expands the output to the number of output pins suitable for the fabric of the FPGA. The embodiment illustrated in FIG. 4 enables a pair or plurality of FPGAs to be interconnected via the input and output serializer/deserializers 401 and 403, respectively, such that the interconnections may run at significantly higher speeds than the prior shift register based systems.

In the exemplary embodiment illustrated in FIG. 4, the input serializer/deserializer 401 and the output serializer/deserializer 403 are physical blocks, that is, hard logic, within the FPGA and may provide a 10:1 pin multiplexing ratio. The output expansion block 421 and input expansion block 423 may be implemented via the reconfigurable logic of the FPGA fabric to expand the 10:1 pin multiplexing ratio provided by the input serializer/deserializer 401 and the output serializer/deserializer 403, to achieve, for example, 30:1 pin multiplexing ratios in accordance with the embodiments. It is to be understood that, although not shown in detail in all other FIGs. for simplicity, various clocks are present that provide appropriate clock signals at the various stages. Therefore, a main system clock 325 is present in the embodiments, as well as clocks to drive the various levels of multiplexing. For example, a stage 1 clock 433 provides a clock to the output expansion block 421 and input expansion block 423. A second clock, stage 2 clock 435, provides a clock to the input serializer/deserializer 401 and the output serializer/deserializer 403. The various clocks may be implemented by division or multiplication of the main system clock 325 to form a clock tree, however any suitable approach for providing the clocks remain in accordance with the embodiments. Therefore, in FIG. 4, CLK 433 and CLK 435 may include logic to multiply or divide the main system clock, CLK 325, as needed.

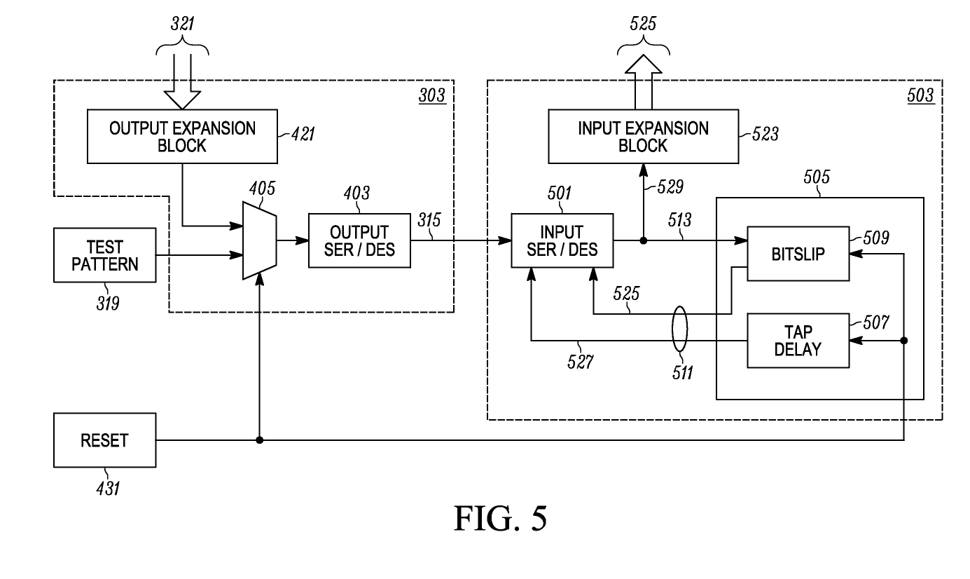

FIG. 5 illustrates interconnection and timing adjustment in accordance with the embodiments. The output portion of the I/O 300 mux/demux 303 is shown on the left hand portion of FIG. 5. The output serializer/deserializer 403 provides the single multiplex output trace line 315 to an input serializer/deserializer 501 of another FPGA mux/demux logic 503. In accordance with the embodiments after the entire system is powered on, or a reset 431 is received, the timing adjustment logic 505 synchronizes the received input to the expected, a priori known test pattern. The reset provides, via a reset bus, a mux reset 413 to the mux 405 and also provides a reset to the timing adjustment logic. The mux/demux 503 relates to a receiving FPGA I/O. After the reset signal is applied, a test pattern 319 is provided to the output serializer/deserializer 403 via, for example the mux 405. The test pattern is then output over trace line 315 to the input serializer/deserializer 501, which provides a input feedback signal 513 to the timing adjustment logic 505. Specifically, the input feedback signal 513 is provided to the bitslip logic 509. The bitslip logic 509 is a priori aware of the test pattern provided by test pattern logic 319. In other words, each FPGA I/O has a test pattern logic similar to test pattern logic 319 which includes the identical test pattern.

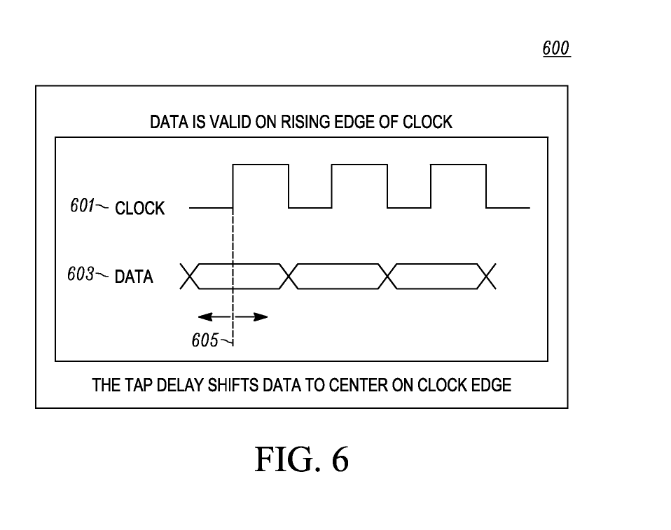

Therefore, each FPGA is a priori aware of the test pattern, and the FPGA's corresponding bitslip logic, such as bitslip logic 509, monitors the input feedback signal 513 to see if it compares with, and agrees with, the a priori known test pattern. If there is a disagreement, and the bitslip logic 509 does not perceive the expected test pattern, the bitslip logic 509 provides a bitslip data adjustment signal 525 to the input serializer/deserializer 501. The bitslip adjustment logic 509 may move the input signal by one or more clock cycle durations, so that the received input pattern is shifted until the known test pattern is perceivable. The arrival time of the test pattern input signal to the input serializer/deserializer 501, is impacted by, for example, the physical length of the physical trace line 315. This physical length causes a delay at high frequency speeds, such as the gigahertz range, and therefore the bitslip logic 509 serves to adjust the data signal by the required number of clock cycles to compensate for the delay caused by the physical trace length. The clock skew within the FPGA may also contribute to misalignment of the data signal. This shifting can be considered as the shifting of serial data, as the trace line 315 is a multiplexed data line that provides a time domain multiplexed signal. The time domain multiplexed (TDM) signal represents a multiplexed signal that multiplexes the plurality of input pins 525. The number of output pins 321 is comparable to the number of input pins 525 on the connected receiving FPGA. Therefore, the bitslip logic 509 is in reality adjusting the data received on each pin of the FPGA fabric by adjusting the TDM signal of the trace line 315. It is to be understood that, in FIG. 5, the transmitting mux/demux 303 also has a comparable receiving portion. Likewise, the receiving mux/demux 503 has a corresponding output portion which is not shown in FIG. 5 for simplicity. It is therefore to be understood that when applying the test pattern and synchronization process of the various embodiments, all input and output connections between various FPGAs are synchronized using the test pattern. In addition to the bitslip logic 509 adjusting the received data to match the a priori known test pattern, the tap delay logic 507 also performs an adjustment on the data. FIG. 6 shows the data signal 603 in conjunction with the clock signal 601. When the clock signal rising edge 605 is too close to the edge of the data signal 603, the tap delay logic 503 shifts the data to be centered on the clock edge as shown in the timing diagram 600 illustrated in FIG. 6.

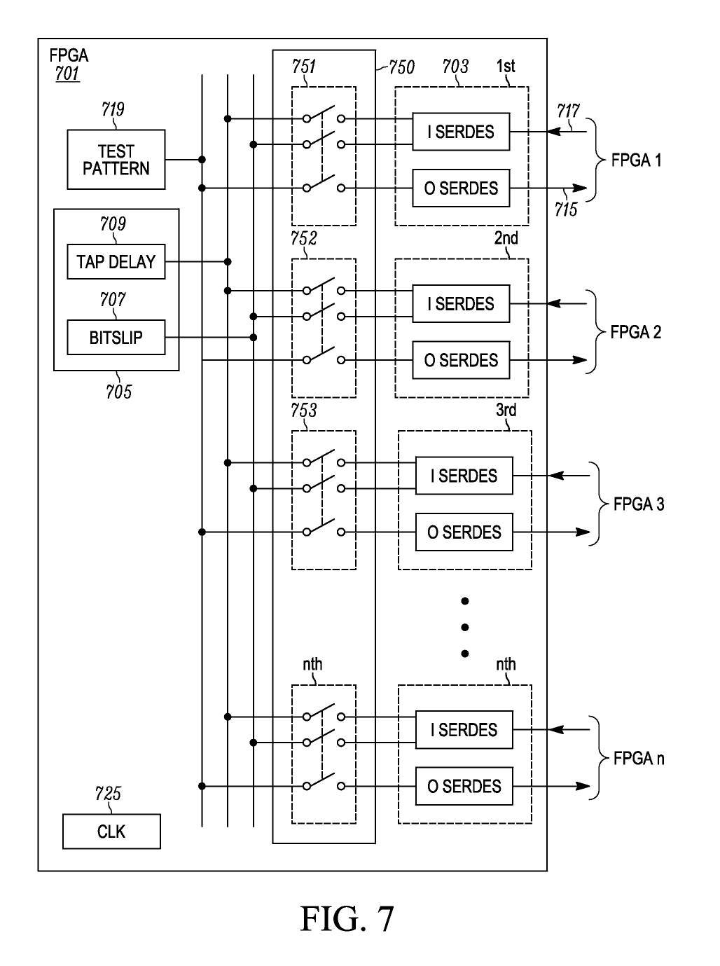

FIG. 7 illustrates an FPGA 701 that may be connected to a plurality of FPGAs, that is, FPGA 701 is connected to FPGA 1 through FPGA n. In the embodiment illustrated in FIG. 7, a switching logic 750 is applied such that a single test pattern logic 719 may be used for the plurality of mux/demux blocks 703. For simplicity of explanation, the mux/demux 703 blocks shown in FIG. 7 are shown in a simplified manner over what was previously described with respect to FIGS. 3, 4 and 5. In addition to the single test pattern logic 719, the I/O also includes the timing adjustment logic 705 and its corresponding bitslip adjustment logic 709 and tap delay logic 707. The switching logic 750 comprises a plurality of logical switch sets such as logical switch set 751, 752 and 753, up through an nth logical switch set. Each logical switch set corresponds to a mux/demux block 703. Thus upon a reset signal which would reset the logical switches in switch logic 750, in addition to the various mux/demux block 703 of the I/O, the switching logic 750 may sequentially apply the test pattern to the input and output serializer/deserializers to synchronize the mux/demux block with its corresponding connected FPGA.

For example, the first mux/demux 703 may be synchronized to FPGA 1 by closing the logical switches 751, thereby connecting the test pattern and timing adjustment logic 705 to the mux/demux 703. After the test pattern is seen by the input serializer/deserializer, the switching logic may sequentially open the logical switches 751 and close logical switches 752 to connect the second input/output serializer/deserializer to FPGA 2 such that the test pattern may be received from FPGA 2. The tap delay logic 707 and bitslip adjustment logic 709 will operate to adjust the input serializer/deserializer in accordance with the receive test pattern. This process may repeat until the end mux/demux has been synchronized. In other embodiments, each mux/demux block such as mux/demux block 703 may have its own corresponding timing adjustment logic 705 and may only be switched to the test pattern logic 719 by the switching logic 750. In yet another embodiment, each mux/demux block 703 may have its own corresponding timing adjustment logic 705 and test pattern logic 715 similar to the embodiments shown in FIG. 3 and FIG. 4. FIG. 7 also illustrates a clock, CLK 725, which represents the main system clock, and a clock tree (not shown) that provides clocks to the various stages of multiplexing as was described above with respect to various clocks shown in FIG. 4.

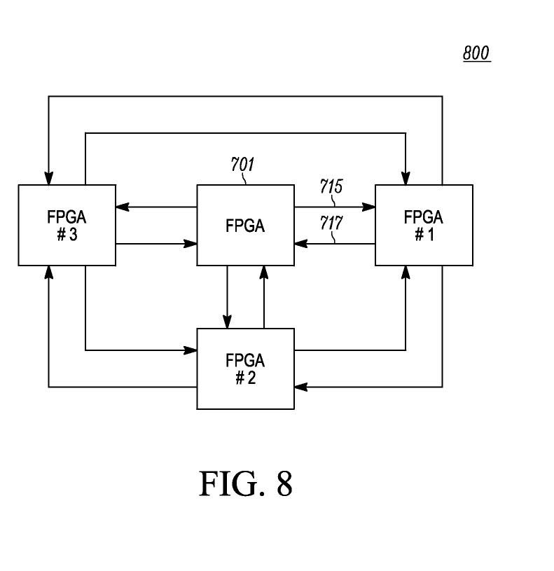

FIG. 8 illustrates the FPGA 701 of FIG. 7 connected in an array of FPGAs 800. The FPGA 701 provides an output trace line 715 to FPGA 1, and receives an input trace line 717 from FPGA 1. Similarly, FPGA 1 is connected to FPGA 2 and FPGA 3. FPGA 2 is further connected to FPGA 701 and to FPGA 3. FPGA 3 is connected to FPGA 701 and also to FPGA 1. Therefore, each of the connections shown in the FPGA array 800 may be synchronized using the methods and apparatus of the various embodiments herein described. The FPGA array 800 illustrated in FIG. 8 is only an example of the many configurations of FPGA arrays that may be achieved using the various embodiments. Because of the high speed available for connectivity by using the various embodiments, many FPGAs can be connected and achieve a high rate of interconnect speed for the array versus what was previously possible using previous systems.

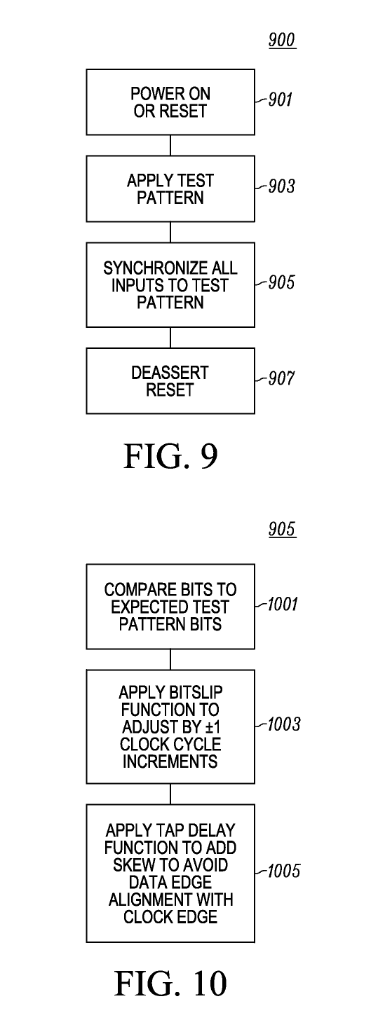

FIG. 9 illustrates the basic method of the embodiments. In 901 power is turned on for the FPGA array or a reset signal is applied. In 903 a test pattern is applied to the outputs of various FPGAs. At the inputs of the receiving FPGAs the inputs are synchronized to the a priori known test pattern as the bitslip logic in the corresponding receiving FPGAs has the a priori knowledge of the test pattern. This is shown in 905. Lastly, if a reset was applied in 901, the reset is deasserted as shown in 907, and the FPGAs are then synchronized and operational to send and receive data.

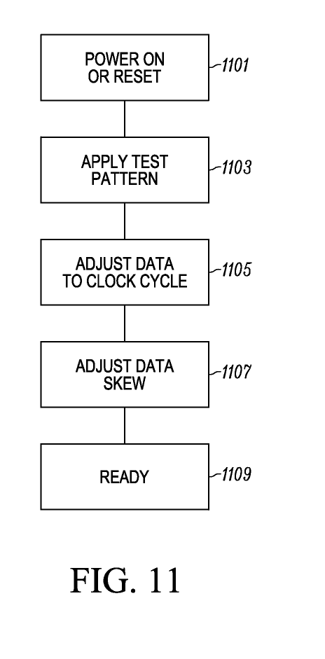

FIG. 10 shows further details of block 905. In 1001 the bits of the received signal are compared to the expected test pattern bits. In 1003 the bitslip function is used to adjust the received data by increments of one clock cycle, in either the forward or backward direction. In 1005 the tap delay function is applied to prevent data edge alignment of the data edge with the clock signal edge. FIG. 11 provides a high level summary of the operation of the various embodiments. For example, in 1101 power to the FPGA array is turned on or a reset signal is applied. In 1103 a test pattern is applied. In 1105 the data is adjusted to the clock cycle using the known test pattern. In 1107 the data is adjusted for skew such that the edges of the data are avoided from corresponding to the edges of the clock signal. And in 1109 the FPGA is ready to run applications or perform other processing.

The devices herein described, in accordance with the various embodiments, may, in whole or in part, be the result of the processing of hardware description language (HDL) instructions and/or data. That is, the HDL instructions and/or data may be used to configure a manufacturing process to manufacture a programmable processor (and/or “logic” as described herein) such that when the programmable processor (and/or “logic”), when configured (through the use of software and/or firmware) is operable to perform the methods in accordance with the embodiments herein disclosed. Such HDL code (or a Netlist) may be stored on a computer readable medium such as, but not limited to, a server memory, CD, DVD, or other non-volatile memory that may provide code to be executed by one or more processors of the manufacturing process.

Therefore apparatuses and methods for achieving high speed data multiplexing in field programmable gate array devices have been disclosed herein. Such high speed multiplexing is obtained by using serializer/deserializer logic and providing a capability to synchronize the input/output logic at each connected FPGA using an a priori known test pattern. Other variations that would be equivalent to the herein disclosed embodiments may occur to those of ordinary skill in the art and would remain in accordance with the scope of embodiments as defined herein by the following claims.

What is claimed is:

1. A processor comprising:
input/output (I/O) logic including timing adjustment logic operative to synchronize a time division multiplexed (TDM) line of said I/O logic using an a priori known test pattern.

2. The processor of claim 1, wherein said timing adjustment logic further comprises:
clock cycle data alignment logic, operative to adjust data on said TDM line by increments of a clock cycle to match said a priori known test pattern; and
skew logic operative to prevent leading or trailing edges of said data from aligning with edges of a clock pulse leading or trailing edge.

3. The processor of claim 2, wherein said I/O logic comprises Serializer/Deserializer (SerDes) logic operative to provide a TDM output and operative to receive a TDM input.

4. The processor of claim 1, wherein said timing adjustment logic, comprises a state machine operative to control said clock cycle data alignment logic and skew logic to adjust said data to match said a priori known test pattern.

5. The processor of claim 1, comprising a plurality of I/O logic blocks, each input/output (I/O) logic block operative to interface to another processor.

6. The processor of claim 5, further comprising:
switching logic operatively coupled to said plurality of I/O logic blocks, and operatively coupled to said timing adjustment logic, wherein each I/O logic block is operative to provide I/O connections with another processor, said switching logic operative to connect said timing adjustment logic to each I/O logic block of said plurality of I/O logic blocks, one at a time in a serial manner, to synchronize each said each I/O logic block one at a time in a serial manner.

7. The processor of claim 5, further comprising:
a plurality of timing adjustment logic blocks, each timing adjustment logic block operatively coupled to a corresponding I/O logic block, wherein each timing adjustment logic block is operative to synchronize its corresponding I/O logic block.

8. The processor of claim 1, further comprising a test pattern logic for sending said a priori known test pattern to another processor over a TDM output line.

9. A multiplexer/de-multiplexer (mux/demux) logic comprising:
timing adjustment logic operative to synchronize a time division multiplexed (TDM) output line of said mux/demux logic using an a priori known test pattern.

10. The mux/demux logic of claim 9, wherein said timing adjustment logic further comprises:
clock cycle data alignment logic, operative to adjust data on said TDM line by increments of a clock cycle to match said a priori known test pattern; and
skew logic operative to prevent leading or trailing edges of said data from aligning with edges of a clock pulse leading or trailing edge.

11. The mux/demux logic of claim 10, wherein said mux/demux logic is a (field programmable gate array) FPGA Serializer/Deserializer (SerDes) logic operative to provide a TDM output and operative to receive a TDM input.

12. The mux/demux logic of claim 10, wherein said timing adjustment logic, comprises a state machine operative to control said clock cycle data alignment logic and skew logic to adjust said data to match said a priori known test pattern.

13. The mux/demux logic of claim 9, operative to interface to another mux/demux logic on an FPGA.

14. The mux/demux logic of claim 12, wherein said state machine operatively controls said clock cycle data alignment logic using a BITSLIP logic and controls said skew logic using a tap delay logic.

15. An FPGA comprising the mux/demux logic of claim 9.

16. A computer readable memory comprising:
executable instructions for execution by an integrated circuit production system, that when executed cause said integrated circuit production system to produce an integrated circuit comprising a timing adjustment logic, said timing adjustment logic operative to:
synchronize a time division multiplexed (TDM) line of an integrated circuit I/O logic using an a priori known test pattern.

17. The computer readable memory of claim 16, wherein said timing adjustment logic further comprises:
clock cycle data alignment logic, operative to adjust data on said TDM line by increments of a clock cycle to match said a priori known test pattern; and
skew logic operative to prevent leading or trailing edges of said data from aligning with edges of a clock pulse leading or trailing edge.

18. The computer readable memory of claim 17, wherein said I/O logic comprises:
Serializer/Deserializer (SerDes) logic operative to provide a TDM output and operative to receive a TDM input, and comprising said timing adjustment logic, wherein said timing adjustment logic comprises a state machine operative to control said clock cycle data alignment logic and skew logic to adjust said data to match said a priori known test pattern.

19. The computer readable memory of claim 16, wherein said executable instructions are in an hardware description language (HDL) or RTL format.

20. An array of FPGAs, each FPGA of said array comprising:
a plurality of multiplexer/de-multiplexer (mux/demux) logic blocks, each block comprising:
timing adjustment logic operative to synchronize a time division multiplexed (TDM) input line of said mux/demux logic using an a priori known test pattern received over said TDM input line from a corresponding mux/demux logic block of a connected FPGA.

21. The array of FPGAs of claim 20, wherein said timing adjustment logic of each FPGA further comprises:
clock cycle data alignment logic, operative to adjust data on said TDM line by increments of a clock cycle to match said a priori known test pattern; and
skew logic operative to prevent leading or trailing edges of said data from aligning with edges of a clock pulse leading or trailing edge.

22. The array of FPGAs of claim 20, wherein said mux/demux logic of each FPGA is an FPGA Serializer/Deserializer (SerDes) logic operative to provide a TDM output and operative to receive a TDM input.

23. The array of FPGAs of claim 22, wherein said timing adjustment logic of each FPGA, comprises a state machine operative to control said clock cycle data alignment logic and skew logic to adjust said data to match said a priori known test pattern.

24. The array of FPGAs of claim 20, wherein each FPGA, sends said a priori known test pattern to every other connected FPGA over a TDM output line.
